(19) United States
(12) Patent Application Publication
(10) Pub. No.: US 2017/0362697 A1
(43) Pub. Date: Dec. 21, 2017

(54) TRANSPARENT AND HIGHLY STABLE SCREEN PROTECTOR

(71) Applicant: SILTECTRA GmbH, Dresden (DE)

(72) Inventors: Jan Richter, Dresden (DE); Wolfram Drescher, Dresden (DE)

(21) Appl. No.: 15/544,032

(22) PCT Filed: Jul. 6, 2015
(86) PCT No.: PCT/EP2015/065345

§ 371 Date: Jul. 17, 2017

(30) Foreign Application Priority Data
Jan. 28, 2015 (DE) 102015001041.7
Mar. 16, 2015 (DE) 102015003369.7

(51) Int. Cl. C23C 16/01; B23K 26/00; C23C 14/00; C23C 14/08; C23C 16/40; C23C 16/56; C23C 14/58; G06K 9/00; A42B 3/22; G02C 7/02; G06F 3/041

(52) U.S. Cl. CPC C23C 16/01; C23C 16/56; B23K 26/0087; C23C 14/0005; C23C 14/081; C23C 14/5813; C23C 16/403; A42B 3/22; G02C 7/02; G02C 2202/16; G06F 3/041; G06F 2203/04107; G06K 9/00053

(57) ABSTRACT

The invention relates to a method for producing at least one solid layer and comprises at least the steps of: providing a carrier substrate (4) having a sacrificial layer (8) arranged thereon or arranging a sacrificial layer (8) on the provided carrier substrate (4), producing a useful layer (6) by way of chemical or physical gas phase deposition on the sacrificial layer (8) to form a multi-layer arrangement (2), removing the useful layer (6) as a result of a material weakening produced between the useful layer (6) and the carrier substrate (4), said material weakening being brought about by modifications (12) to the sacrificial layer (8) which were produced means of laser beams (10).

The present invention relates to a method for producing at least one solid layer according to claim 1, a method for coating at least one transparent body in accordance with claim 2, a multilayer transparent protective device according to claim 15, and an electronic apparatus according to claim 16.

Displays of mobile phones, laptops, tablets, MP3 players, etc. are often used as a display and input device, and more particularly as a touch screen. This means that such displays are touched often. Furthermore, smaller devices such as mobile phones and MP3 players are put in pockets, where they often come into contact with keys, coins and other hard objects. This contact can cause the surface of the display to become scratched. Unfortunately, scratches have the effect of lowering display quality and reducing input accuracy.

There have been continuous known attempts to produce more stable display glasses. By the Corning company, for example, a special process was developed to modify the strength of glass so that it could be used as display glass called “Gorilla Glass”.

The use of aluminium oxide is also known for forming sapphire glass for watches which is extremely insensitive to damage, such as scratches due to its hardness.

The known “Gorilla Glass” is less hard than sapphire, but sapphire is more brittle. Both versions also result in thick and/or heavy structures.

The production of sapphire glass also requires extremely temperature-resistant tools, process materials and equipment, as temperatures above 500° C. can occur. Aluminium oxide can also be generated as a layer on a temperature-resistant material, by sputtering for example. Such coating methods have been part of the prior art for many years and are identified and described for example by Zywitzki et al., “Structure and properties of Al₂O₃ layers deposited by plasma activated electron beam evapouration” in Surface and Coating Technology p. 14-20 from 2002 or by Zywitzki and Hoetzsch “Correlation between structure and properties of reactively Deposited Al₂O₃ coating by pulsed magnetron sputtering” in Surface and Coatings Technology p. 303-308 from 1997 or by Erklund et al., “Thermal Stability and Phase Transformations of γ-/Amorphous-Al₂O₃ Thin Films” in plasma Process. Polym. p. 907-911 from 2009. It is also apparent that due to the high temperatures used when coating with Al₂O₃ only very highly heat-stable materials can be coated with Al₂O₃.

It is therefore the object of the present invention to provide a method for the preparation of a solid layer, a method for coating at least one transparent body, an electronic device and a multilayer transparent protective device which eliminate/s at least one of the disadvantages of the prior art or offer an alternative thereto. It is particularly an object of the present invention to provide a method for producing a touchscreen panel wherein the display is both scratch-resistant and inexpensive to produce.

The abovementioned object is achieved according to the invention with a method for producing a solid layer according to claim 1. The inventive method for producing at least one solid layer preferably comprises thereby at least the steps of: providing a carrier substrate with a sacrificial layer disposed thereon or disposing a sacrificial layer on the carrier substrate provided, creating a wear layer, particularly by chemical or physical vapour deposition, on the sacrificial layer to form a multilayer arrangement, separating the wear layer through a material weakness created between the wear layer and the carrier substrate, wherein the material is weakened by modifications induced in the sacrificial layer by LASER beams, or separating the wear layer by means of a crack conducted between the wear layer and the carrier substrate, wherein the crack is conducted by the modifications induced in the sacrificial layer by LASER beams. According to the present invention, therefore, the crystal structure in the separation zone is modified or damaged by means of LASER beams in such manner that the wear layer becomes detached and so separated from the rest of the multilayer arrangement as a result of the LASER treatment. The separated wear layer is thus the produced solid layer. This solution is advantageous because a very thin wear layer can be produced and can be separated from a sacrificial layer with only minor material losses. In this context, the sacrificial layer is not as resistant as the carrier substrate or the wear layer. However, it is also conceivable that the strength of the sacrificial layer is reduced only as a result of the creation of modifications in the sacrificial layer. The sacrificial layer may be designed to be very thin, particularly thinner than would be necessary is the sacrificial layer were to be separated by sawing, so that it can be produced both quickly and inexpensively.

According to claim 2, the present invention further relates to a method for coating at least one transparent body, particularly a display glass or a display protective layer. The inventive method for coating at least one transparent body then preferably comprises at least the step of placing or generating the at least partially transparent body, particularly made of plastic, glass or a ceramic material, on a wear layer prepared according to claim 1. Alternatively, the method may comprise the steps of providing a carrier substrate with a sacrificial layer disposed thereon or placing a sacrificial layer on the carrier substrate provided, generating a wear layer on the sacrificial layer by chemical or physical vapour deposition to form a multilayer arrangement, placing or generating the at least partially transparent body on the wear layer and separating the wear layer as a result of a material weakness created between the wear layer and the carrier substrate, wherein the weakness in the material is produced by modifications in the sacrificial layer generated by means of LASER beams, or separation of the wear layer by a crack conducted between the wear layer and the carrier substrate, wherein the crack is conducted by modifications produced in the sacrificial layer by means of LASER beams. This solution is advantageous because the wear layer produced may also be arranged on materials which are not suitable designed to be exposed to the high temperatures at which the wear layer is produced, that is to say during chemical or physical vapour deposition, particularly sputtering or plasma-activated sputtering. It is particularly advantageous if the wear layer produced is disposed on an inexpensively manufactured plastic or similar material which is not designed to undergo chemical or physical vapour deposition, particularly plasma-activated sputtering, due to the high temperatures involved. It is also conceivable that the transparent body is generated on the wear layer, particularly by curing. The carrier substrate preferably consists of a metal or ceramic material, and the sacrificial layer is preferably composed of silicon or a silicon compound or carbon or a carbon compound.

Further preferred embodiments are the objects of the following descriptions and/or the dependent claims. According to a preferred embodiment of the present invention, the at least partially transparent body is made of a polymer material, wherein the material of the transparent body has a lower modulus of elasticity than the material of the wear layer, particularly a modulus of elasticity that is lower than the modulus of elasticity of the wear layer material by at least a factor of 10 or a factor of 100. This embodiment is advantageous because any slight break resistance in the wear layer is significantly increased by the polymer material transparent body. The multilayer arrangement thus particularly preferably consists of an at least partially transparent body, particularly a transparent polymer layer, and an at least partially transparent wear layer, thereby preferably together forming a thin, lightweight structure which is highly resistant to scratches and has high break resistance.

It is advantageous if the wear layer substantially as a solid layer with a two-dimensional plane and the transparent body has and external form with at least one curved portion, wherein the wear layer is applied to the transparent body in such manner, particularly by bonding or gluing, that the wear layer conforms to the external form of the transparent body. In this way, displays having a scratch-resistant surface may be produced with various three-dimensional geometric shapes such as convex, concave or spherical displays can be manufactured inexpensively. According to a further preferred embodiment of the present invention, the wear layer and the transparent body have an comprise external form with at least one curved portion. Preferably, the modifications are created for conducting the crack in the sacrificial layer and/or the wear layer corresponding to the external form of the wear layer or a portion of the external form of the wear layer, particularly a surface portion of the wear layer. Additionally or alternatively, however, it is also conceivable that the sacrificial layer is produced with such a curved designed surface or the surface of the sacrificial layer is processed after the creation of the sacrificial layer so that it forms a curved surface shape, and that by its production the wear layer is conformed correspondingly on the curved surface the sacrificial layer or conformed negatively to the curved surface of the sacrificial layer. This embodiment is advantageous because curved protective devices or screen protector layers could be used e.g. for watches, especially “smart watches” or mobile phones, so that the respective device may be given a shape adapted to the body of a person for example, and/or provides ergonomic advantages.

The inventive method preferably comprises the steps of placing or generating a stress-inducing layer on at least one exposed surface of the multilayer arrangement and the step of applying a thermal load to the stress-inducing layer to generate the mechanical stresses within the multilayer assembly, wherein the stresses generated in the portion of the multilayer arrangement constituted by the donor wafer become so great that a crack forms along the detachment zone in the donor wafer, as as result of which the donor wafer is cleaved to yield the separated part and the connected part, wherein the stress-inducing layer comprises or consists of a polymer, particularly polydimethylsiloxane (PDMS), wherein the thermal shock is performed such that the polymer undergoes a glass transition, wherein the temperature of the stress-inducing layer is adjusted, particularly by means of liquid nitrogen, to a temperature at which the polymer at least partially and preferably completely undergoes glass transition, and in this context the temperature of the polymer is adjusted preferably to a temperature below room temperature or below 0° C. or below −50° C. or below −100° C. or below −110° C., particularly to a temperature below the glass transition temperature of the stress-inducing layer. This embodiment is advantageous because it has been found that the forces required for initiating and conducting can be created in a donor substrate by applying a thermal load to the stress-inducing layer, particularly by exploiting the property changes that take place in the material at the glass transition. The application of the thermal load to the stress-inducing layer can also be timed very precisely to control when the solid layer or solid wafer is separated and/or the multilayer arrangement is split. Alternatively however, the stress-inducing layer may include or consist of a polymer with a glass transition temperature above room temperature. Thus, polymers such as the thermoplastics PMMA (polymethyl methacrylate, commonly known as Plexiglas) and PS (polystyrene) have glass transition temperatures between 40° C. and 180° C., particularly between 60° C. and 110° C. The thermoplastic PEEK (polyether ether ketone) for example has a glass transition temperature of 143° C. and a melting temperature of 335° C. This is particularly advantageous because a cooling process of the polymer to room temperature and the associated glass transition can be integrated in the polymer manufacturing process and the polymer may be bonded to the wear layer. Accordingly, it may be possible that the polymer and the last layer of the multilayer arrangement are identical, and consequently that the polymer is coated with the wear layer and simultaneously serves as a stress-inducing layer. However, it is also possible to apply a thermal load to the polymer by heating separately from the polymer manufacturing process and so induce a glass transition again during the subsequent cooling of the polymer. The thermal shock for inducing stresses may thus also be carried out in a step of increasing the temperature during the process. The mechanical stresses may be generated additionally or alternatively by total mechanical vibrations and/or temperature changes and/or pressure changes, particularly changes in air pressure. According to another preferred embodiment of the present invention, the wear layer consists of a ceramic material, particularly silicon carbide (SiC) or aluminium oxide (Al₂O₃), which is produced in the amorphous or polycrystalline form particularly by sputtering. The wear layer is preferably cured after or during production of the wear layer by thermal treatment at temperatures above 500° C. preferably above 700° C. and particularly preferably above 1000° C. or above 1100° C. The ceramic material is particularly preferably corundum, which is preferably grown in a first phase and converted from a first phase to a second phase at least partially and preferably mostly (particularly in terms of volume) and particularly preferably completely as a result of the thermal shock. The first phase is preferably a gamma-phase of the corundum and the second phase is preferably an alpha-phase of the corundum.

According to a further preferred embodiment of the present invention, the wear layer is thinner than 100 μm and preferably thinner than 50 μm and particularly preferably 20 μm thick or thinner than 20 μm. The sacrificial layer is additionally or alternatively thinner than 10 μm and preferably thinner than 5 μm and particularly preferably 1 μm thick or thinner than 1 μm. This embodiment is advantageous because a wear layer or protective layer which is significantly less vulnerable to damage, particularly more scratch-resistant than glass can be produced with a small quantity of material.

According to a further preferred embodiment of the present invention, the modifications have the form of local cracks in the crystal lattice and/or conversion of material parts into another phase. This embodiment is advantageous because the modifications make it possible to determine the crack conducting zone and/or control the crack propagation very precisely.

According to a further preferred embodiment of the present invention, the modifications are created by LASER beams by at least one picosecond or femtosecond LASER penetrating the interior of the multilayer arrangement though an outer surface of the multilayer arrangement.

According to a further preferred embodiment of the present invention, the individual modifications or faults or damage sites are caused by a multi-photon excitation from each LASER, particularly a femtosecond LASER or a picosecond LASER. The LASER preferably has a pulse duration shorter than 10 ps, particularly preferably shorter than 1 ps, most preferably shorter than 500 fs.

According to a further preferred embodiment of the present invention, the energy of the LASER beam, particularly of the fs LASER, is selected such that the damage propagation in the sacrificial layer or in the wear layer is less than three times the Rayleigh length, particularly preferably less than the Rayleigh length and particularly preferably less is one third of the Rayleigh length. According to a further preferred embodiment of the present invention, the wavelength of the LASER beam, particularly of the fs LASER is chosen such that its absorption by the sacrificial layer and the material is less than 10 cm⁻¹, and preferably less than 1 cm⁻¹, and most preferably less than 0.1 cm⁻¹.

According to a further preferred embodiment of the present invention, the LASER-beams are emitted by at least a LASER device, wherein the LASER device for delivering the LASER beams into the wear layer and/or the sacrificial layer is configured such that the LASER beams emitted thereby create the modifications at predetermined locations in the wear layer and/or the sacrificial layer, wherein the LASER device is preferably adjusted such that the LASER beams emitted thereby for creating the modifications penetrate the wear layer and/or the sacrificial layer to a defined depth of less than 200 μm, preferably less than 100 μm and more preferably less than 50 μm and particularly preferably less than 20 μm, wherein the LASER device has a pulse duration of less than 10 ps, preferably less than 1 ps and particularly preferably less than 500 fs. This embodiment is advantageous because it allows very precise and rapid creation of the modifications.

According to another preferred embodiment, the LASER device comprises or consists of a femtosecond LASER (fs-LASER). The energy of the LASER beams from the fs-LASER is preferably selected such that the damage propagation of any modification in the wear layer and/or the sacrificial layer is less than 3 times the Rayleigh length, preferably less than the Rayleigh length and particularly preferably less than one-third of the Rayleigh, and/or the wavelength of the LASER beams of the fs LASER is selected such that the absorption by the wear layer and/or the sacrificial layer is less than 10 cm⁻¹, and preferably less than 1 cm⁻¹ and particularly preferably less than 0.1 cm⁻¹, and/or the individual modifications are each caused as a result of a multi-photon excitation from the fs-LASER. This embodiment is advantageous because suitable modifications can be created without overheating the respective layer or layers. The invention further relates to a multilayer transparent protective device, particularly a screen protector or fingerprint sensor protector, according to claim 15. According to the invention, the multilayer transparent protective device comprises at least one at least partially transparent body and at an least partially transparent wear layer connected to the transparent body, wherein the transparent body consists of a polymer material and the wear layer consists of a ceramic material, wherein the wear layer is harder than the transparent body and wherein the production of the multilayer transparent protective means comprises at least the steps of creating the wear layer by chemical or physical vapour deposition, and arranging, particularly generating or bonding or gluing the transparent body, on the wear layer. This solution is advantageous because high scratch resistance is assured even with a very thin layer of the ceramic material, especially corundum, and high break resistance is assured with a likewise preferably very thin, particularly layered transparent body made of a polymer material. Since both layers may be very thin, the resulting protection device may also be very thin and lightweight.

According to claim 16, the present invention further relates to an electronic device, particularly a smart phone, a tablet PC, a smart watch or a TV device. According to the invention, the electronic device preferably comprises at least one image signal processing device and one display device for outputting an image signal processed by the image signal processing device. Preferably, at least the display device and/or an optically conductive additional part, such as a camera cover or a fingerprint sensor or a separate area of a touch screen or a glasses lens or a watch glass or a visor, particularly a helmet visor or ski goggles is at least partly or completely overlaid with a multilayer transparent protection device according to claim 9.

The carrier substrate and/or the wear layer preferably comprise(s) a material or material combination from one of the main groups 3, 4 and 5 of the Periodic Table of Elements, such as Si, SiC, SiGe, Ge, GaAs, InP, GaN, Al₂O₃ (sapphire), AlN. Particularly preferably, the carrier substrate and/or the wear layer contain(s) a combination of elements occurring in the third and fifth groups of the Periodic Table of Elements. Conceivable materials or material combinations are for example gallium arsenide, silicon, silicon carbide, etc. In addition, the carrier substrate and/or the wear layer may contain or consist of a ceramic (e.g., Al₂O₃—aluminium oxide), preferred ceramics beinf for example perovskite ceramics (e.g., ceramics containing Pb, O, Ti/Zr) in general and lead-magnesium-niobate, barium titanate, lithium titanate, yttrium-aluminium-garnet, particularly yttrium-aluminium-garnet crystals for solid state LASER applications, surface acoustic wave (SAW) ceramics, such as lithium niobate, gallium orthophosphate, quartz, calcium titanate, etc. in particular. The carrier substrate and/or the wear layer therefore preferably include(s) a semiconductor material or a ceramic material, or particularly preferably the carrier substrate and/or the wear layer consist(s) of at least one semiconductor material or a ceramic material. It is further coneeivable that the carrier substrate and/or the wear layer include(s) a transparent material or partly consist(s) of or is/are made from a transparent material, such as corundum, particularly in the alpha phase or the gamma phase. Other materials that may be considered for use as the carrier substrate and/or wear layer either alone or in combination with another material are for example “wide band gap” materials InAlSb, high-temperature superconductors, particularly rare earth cuprates (e.g., Yba2Cu3O7). It is additionally or alternatively conceivable that the carrier substrate and/or the wear layer is/are a photomask, wherein in the present case preferably any photomask material known on the date of submission of the application and particularly preferably combinations thereof may be used as a photomask.

According to a further preferred embodiment of the present invention, more than 5%, particularly more than 10% or more than 20% or more than 30% or more than 40% or more than 50% or more than 60% or more than 70% or more than 80% or more than 90% or more than 95% of the crystal lattice in the course of the separation zone, that is to say in the crack conducting zone defined by the modifications, is changed, particularly damaged by means of the modifications. This embodiment is advantageous because the crystal lattice particularly of the sacrificial layer and/or the wear layer may be changed by the LASER application for example and/or faults, particularly microcracks may be produced therein, in such manner that the forces needed to separate the wear layer from the sacrificial layer can be set up. According to the present invention, the crystal structure in the separation zone is modified or damaged by LASER radiation in such manner that the wear layer is detached from the rest of the multilayer arrangement and is thus separated therefrom as a result of the LASER treatment.

According to a further embodiment of the present invention, any material parts of the sacrificial layer remaining on the wearing surface material are removed in a subsequent step, particularly by polishing. This embodiment is advantageous because the wear layer can be detached from the remnants of the original multilayer arrangement consisting of the carrier substrate, the sacrificial layer and the wear layer with little effort.

The aforementioned object is additionally or alternatively solved with a method for manufacturing a solid layer. The alternative method of the invention comprises at least the steps of: forming or providing a multilayer arrangement consisting of at least one crystalline carrier substrate, one wear layer and one transfer layer, the transfer layer being disposed between the carrier substrate and the wear layer and connected to the carrier substrate and the wear layer, wherein the transfer layer is designed such that it transmits crystal lattice information of the carrier substrate to the wear layer, the wear layer is generated or treated such that it at least partially has a crystal lattice, wherein the crystal lattice is at least partially formed in response to the crystal lattice information provided by the transfer layer, applying LASER beams to at least a portion of the multilayer arrangement for at least partially producing modifications in the transfer layer or in the area of the joint between the transfer layer and the carrier substrate or the wear layer to create a detachment zone, separating the multilayer arrangement along the detachment zone, particularly as a result of LASER impingement. This solution is advantageous because the wear layer produced may be deposited on and/or attached, particularly by bonding or adhesion to a preferably at least partially transparent body, particularly a layer or film.

Furthermore, within the scope of the present invention the wear layer may be joined to a retaining layer, particularly a support, wherein the support does not have to be transparent and is preferably a metallic or ceramic support or panel.

This object is also solved with a method for coating at least one transparent body, particularly a display glass or a display protection layer. The method of the invention preferably comprises at least the steps listed below: Forming or providing a multilayer arrangement which consists at least of a crystalline carrier substrate, a wear layer and a transfer layer. The transfer layer is disposed between the carrier substrate and the wear layer and connected to the carrier substrate and the wear layer. The transfer layer is constructed such that it transmits a crystal lattice information of the carrier substrate to the wear layer, said wear layer being generated or treated in such manner that it at least partially forms a crystal lattice. The crystal lattice is formed at least partially on the basis of the crystal lattice information provided by the transfer layer. Further, the wear layer is connected to the at least partially transparent body, particularly a functional layer. At least a portion of the multilayer arrangement is exposed to LASER beams for at least partially generating modifications in the transfer layer or in the region of the joint between the transfer layer and the carrier substrate or the wear layer for generating a detachment zone. Further, the multilayer arrangement is separated along the detachment zone, particularly as a result of LASER impingement.

This solution is advantageous because the mounting of the wear layer on the at least partially transparent and preferably transparent, particularly completely transparent body means that a coating is provided which has different properties from the properties of the body. Thus, the wear layer may be considerably harder than the body. Preferable, the wear layer partially forms and particularly preferably substantially forms a crystal lattice structure.

According to a preferred embodiment of the present invention, the wear layer is converted from an amorphous state to an at least partially, especially mostly crystalline state as a result of temperature adjustment, wherein the wear layer receives the crystal lattice information provided by the transfer layer when changing states, wherein the temperature adjustment is effected preferably by exposure to an electron beam. This embodiment is advantageous because the wear layer may first be produced simply in amorphous form and with defined dimensions and a conversion of the wear layer into an at least partially crystalline form may then be carried out with low material losses (from the transfer layer).

According to a further preferred embodiment of the present invention, the transfer layer is produced in a crystalline state on the carrier substrate or arranged on the carrier substrate in the amorphous state where it is converted at least partially and preferably mostly or entirely into a crystalline state by a thermal shock. It is thus possible to provide the transfer layer in several ways, wherein the most suitable variant may be selected depending on the requirements of the situation. The transfer layer may also be created very thin, so that any subsequent postprocessing and material losses are reduced.

According to a further preferred embodiment, the carrier substrate and the wear layer are made of the same material, particularly sapphire or silicon carbide, and the transfer layer consists of a different material from that of the carrier substrate and the wear layer, particularly silicon. This embodiment is advantageous because the material of the transfer layer is preferably easy to handle, inexpensive, and softer than the material required to protect a transparent body. Moreover, particularly since it is very thin the transfer layer is able to pass on the crystal lattice information of the carrier substrate to the wear layer.

The subject matters of the patent applications with application numbers PCT/EP2014/071512, DE102013016682.9 and DE102014013107.6 which disclose a modification generation in a solid body by LASER beams are incorporated in the scope of the present invention in their entirety by reference thereto. The subject matters of documents PCT/US2008/012140 and PCT/EP2009/067539, which disclose the separation of solid body layers by means of crack initiation and crack propagation are also incorporated in the scope of the present invention in their entirety. Preferably in all cases in which it is used in the present invention, the word “substantially” defines a deviation in the range of 1%-30%, particularly 1%-20%, particularly 1%-10%, particularly 1%-5%, particularly 1%-2% from the specification that would be indicated if this word were not used.

Further advantages, objects and properties of the present invention will be explained in the following description of the accompanying drawing, in which the inventive production of a multilayer transparent protective device is represented for exemplary purposes. Components or elements in the production of the protective device or electrical device according to the invention that are represented in the figures and at least substantially fulifil equivalent functions may in this case be identified by the same reference numerals, wherein such components or elements do not necessarily need to be numbered or explained in all figures.

In the drawing:

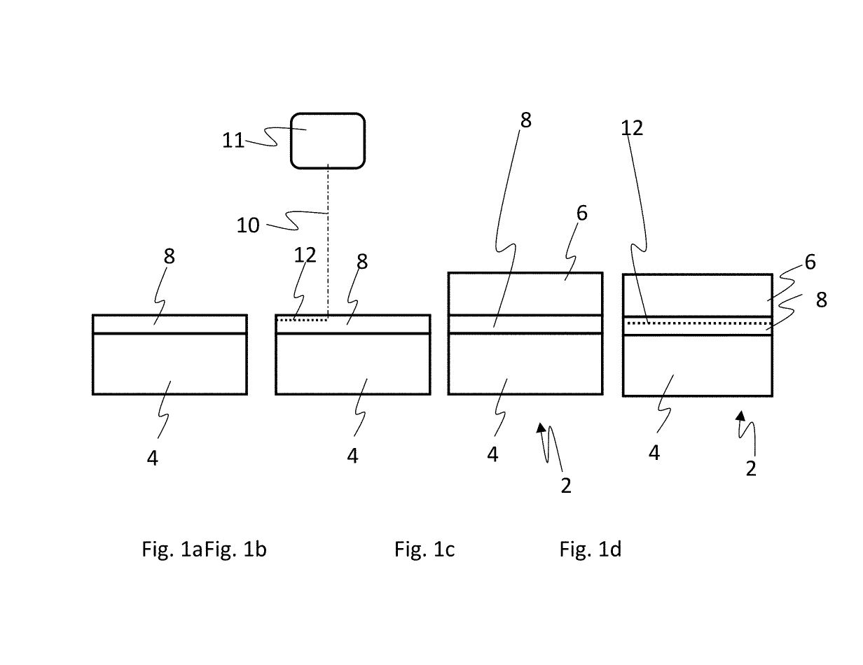

FIGS. 1a-1c show steps for creating a solid layer;

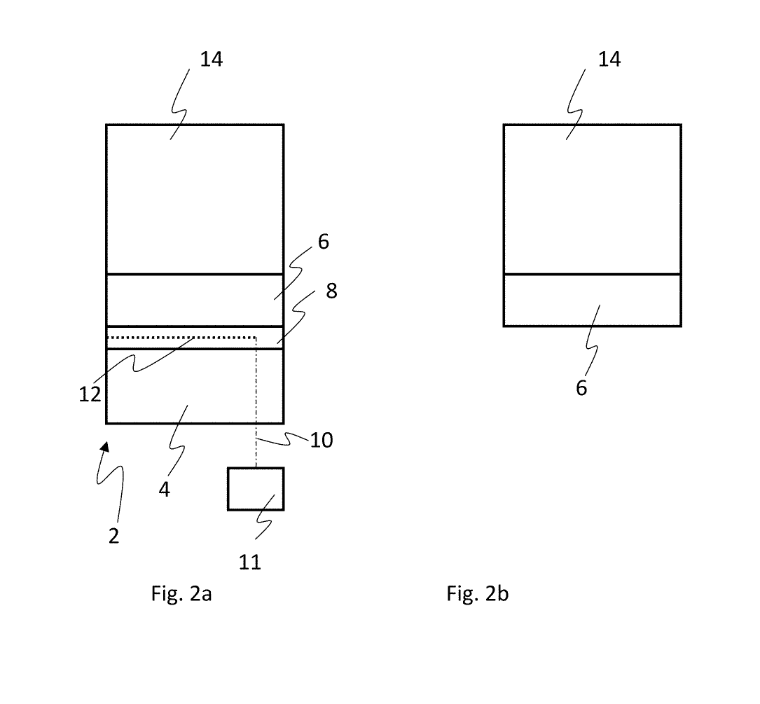

FIGS. 2a-2b show steps for coating a transparent body;

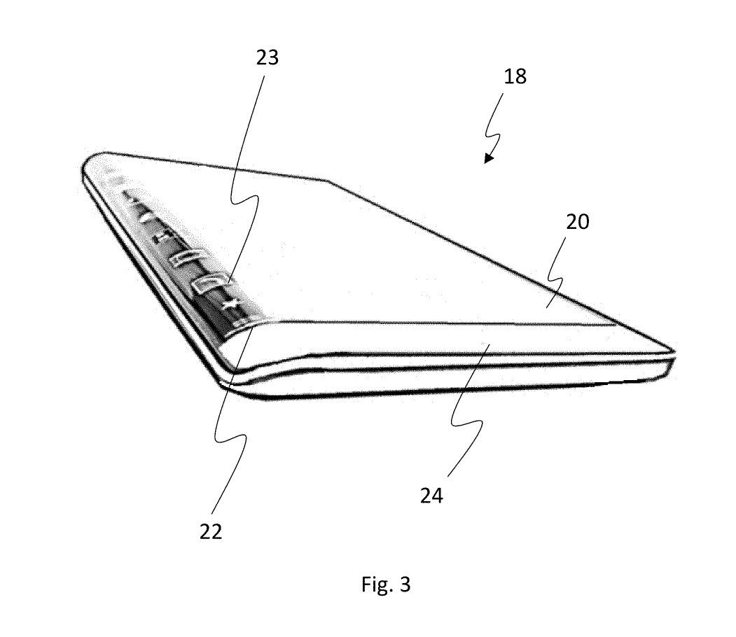

FIG. 3 is a perspective view of an exemplary electronic device having a curved display protector;

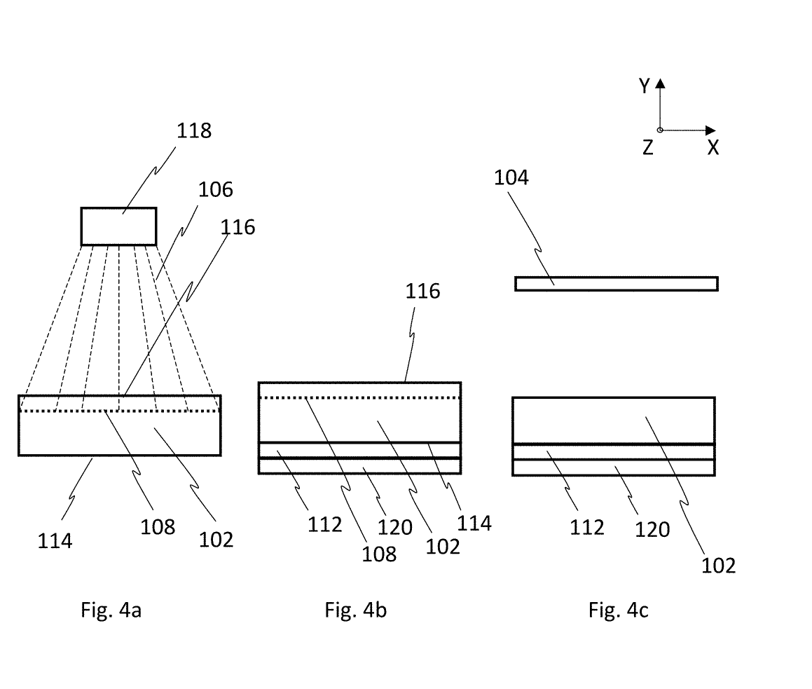

FIG. 4a is a schematic representation of an apparatus for producing modifications in a solid such as the sacrificial layer and/or the wear layer;

FIG. 4b is a schematic representation of a layer arrangement before the separation of a solid layer from a solid body or a multilayer arrangement;

FIG. 4c is a schematic representation of a layer arrangement after the separation of a solid layer from a solid body or a multilayer arrangement;

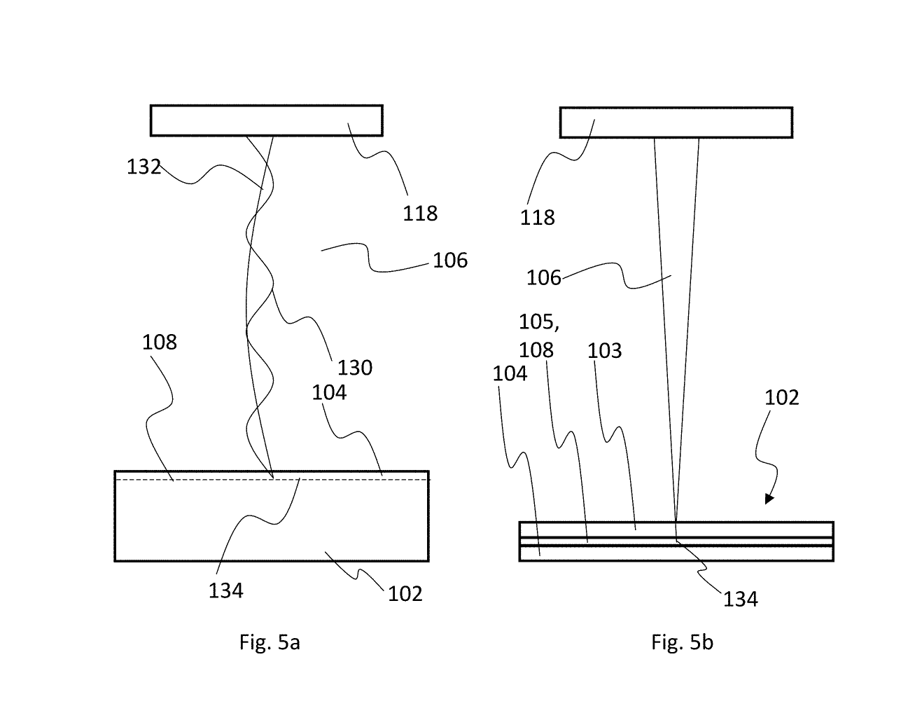

FIG. 5a is a schematic representation of a first variant for creating modifications by means of light waves;

FIG. 5b is a schematic representation of a second variant for creating modifications by means of light waves;

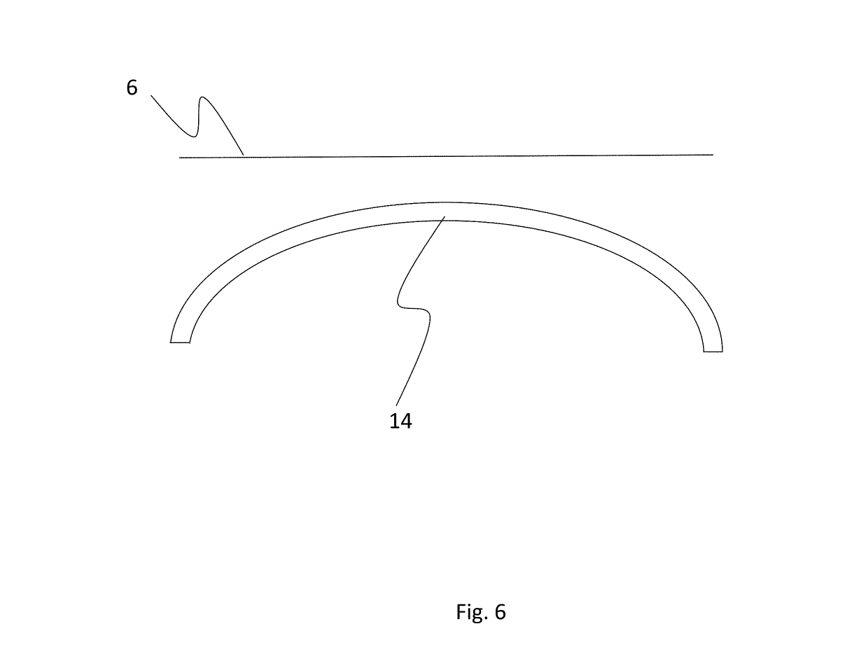

FIG. 6 shows the step of disposing a wear layer on a transparent body;

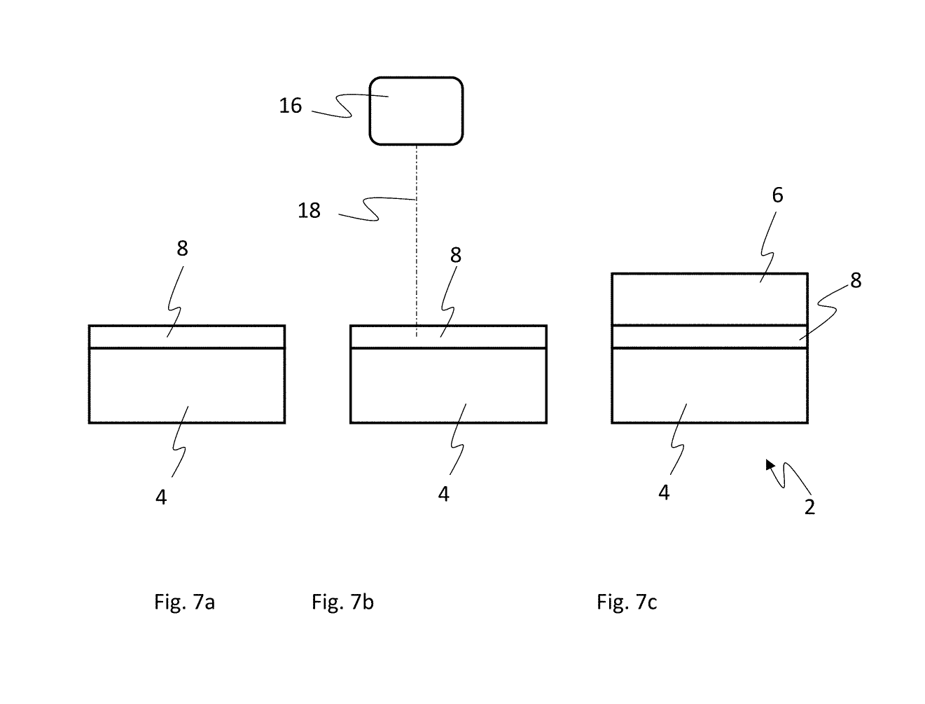

FIGS. 7a-7c show a variant for producing a multilayer arrangement; and

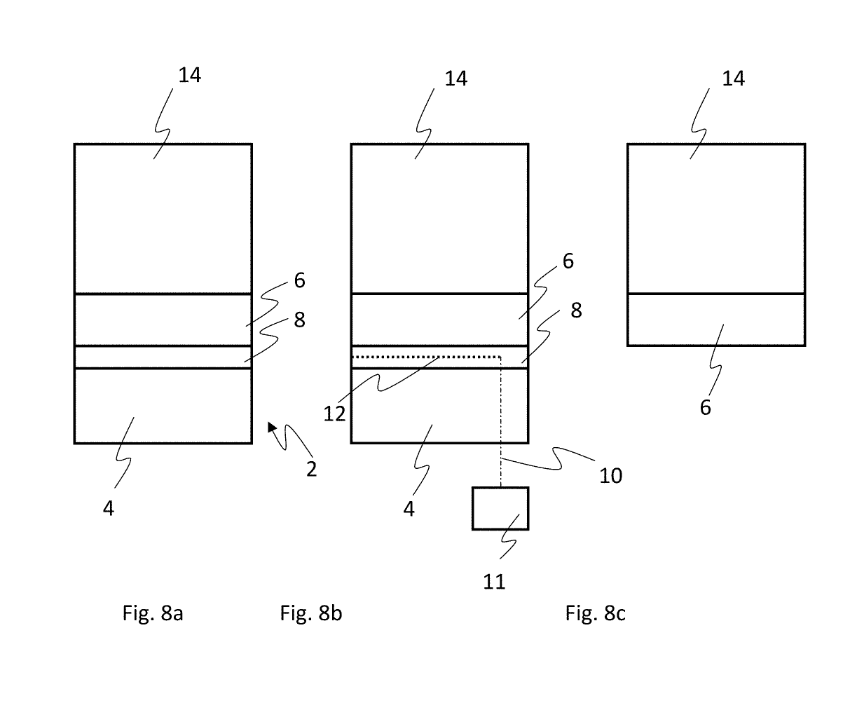

FIGS. 8a-8c show preferred steps of forming the coating of a transparent body according to the invention.

In FIG. 1a, a carrier substrate 4 is shown which preferably consists of a crystalline material, particularly crystalline sapphire or crystalline silicon carbide. Alternatively, however, is also conceivable that the carrier substrate may consist of a metal or a metal alloy, so the carrier substrate may be cast or forged, for example. A sacrificial layer 8 is preferably arranged or formed on carrier substrate 4. Sacrificial layer 8 may thus either be produced on carrier substrate 4 or connected thereto. In this context, sacrificial layer 8 has a thickness of preferably less than 100 μm, particularly less than 50 μm.

In FIG. 1B, as well as the arrangement of FIG. 1A, a LASER device 11 is shown by means of which sacrificial layer 8 is subjected to a load such that modifications 12 are created in the internal structure of sacrificial layer 8. In this context, modifications 12 may be generated in one plane or they may describe a three-dimensional contour. Modifications 12 particularly preferably influence or determine a course of a crack. Additionally or alternatively, the modifications may be generated in wear layer 6 (FIG. 1c). Additionally or alternatively, the generation of modifications 12 may thus take place after the production of wear layer 6. The LASER beams are then preferably introduced through an exposed surface of wear layer 6 or through carrier substrate 4 into sacrificial layer 8 and/or wear layer 6 to produce modifications 12 in sacrificial layer 8 and/or wear layer 6.

FIG. 1c shows a wear layer 6, particularly made of corundum or silicon carbide, which was formed on sacrificial layer 8 by a chemical or physical vapour deposition process. Carrier substrate 4, sacrificial layer 8 and wear layer 6 together form a multilayer arrangement 2. Wear layer 6 preferably has a thickness of less than 100 μm. If wear layer 6 is formed on sacrificial layer 8, wear layer 6 is initially at least partially or mostly (by volume) present in an amorphous or polycrystalline state. Wear layer 6 is then heated, preferably by means of a temperature control such as an electron beam source, so that it is converted for example from a first phase to a second, particularly harder phase. After it has been generated (on sacrificial layer 8) and undergone thermal treatment, most or substantially all of wear layer 6, which particularly preferably consists of or contains corundum is preferably present in a gamma phase of the corundum material or an alpha phase of the corundum material.

In this way, so many modifications 12 are generated that a crack forms and spreads and a weakening of the material is created such that the multilayer arrangement is separated or split or fragmented into two solid parts.

Alternatively within the scope of the present invention, the step described with reference to FIG. 1b may take place after the step described with reference to FIG. 1c. Accordingly, the steps described with reference to FIGS. 1b and 1c may also be carried out in a different order. That is to say, the processing steps or actions described with reference to FIG. 1c may also be effected or carried out before the processing steps or actions described with reference to FIG. 1b. Accordingly, wear layer 6 may be arranged or produced one sacrificial layer 8 first, and then the modifications 12 are created in sacrificial layer 8, in which case LASER beams 10 then penetrate sacrificial layer 8 either through wear layer 6 or through carrier substrate 4.

FIG. 2a shows the production of modifications 12 in sacrificial layer 8 at an alternative time to that shown in FIG. 1b, in particular after a transparent body 14 has been arranged or generated on wear layer 6. The creation of modifications 12 has the effect of separating carrier substrate 4 with at least a part of sacrificial layer 8 from the multilayer arrangement 2 formed by wear layer 6 and transparent body 14. Transparent body 14 may be for example a polymer layer or a display glass, particularly of an electronic device such as a tablet PC or a smart phone. FIG. 2b shows a state after the separation of at least a part of sacrificial layer 8 and carrier substrate 4 from the rest of the arrangement. The separation is preferably carried out in such manner that as much material of sacrificial layer 8 as possible is removed from wear layer 6. This is advantageous because wear layer 6 only requires a small amount of postprocessing, particularly polishing. However, the preferred low total thickness of sacrificial layer 8 means that it is also conceivable that 50% or more of the material parts of sacrificial layer 8 may remain on wear layer 6 upon separation. After the removal of the sacrificial layer parts 8 from wear layer 6, what is produced is a preferably two-layer arrangement consisting of two at least partially transparent materials with different properties, particularly different strengths. Transparent body 14 preferably consists of a glass or a plastic, particularly a polymer, and wear layer 6 is made of a ceramic material, particularly corundum.

FIG. 3 shows an electronic device 18, which in the form shown is preferably a smart phone or a tablet PC. Electronic device 18 is equipped with a display glass 20 or screen protector 20 according to the invention which is formed from at least a wear layer 6 and a transparent body 14 (see. FIG. 2b). Display glass 20 or display protector 20 is preferably designed to be touch-sensitive, so that displayed selection elements 23 may be selected by touching. Reference numeral 24 identifies a frame element which surrounds display protector 20 or display glass 20.

In addition, this representation shows that the screen or display protector 20 has a curved portion 22. This is advantageous because it allows ergonomic or more ergonomic operation of electronic device 18 and an enlargement of the display area. According to a variant which is not shown, however, it is possible that the curved portion comprises the complete display in both a convex concave or a spherical shape.

FIGS. 4a to 5b represent examples of how modifications or faults may be produced in a solid body by means of LASER beams. The creation of modifications or faults illustrated and described hereinafter is preferably applicable in similar manner to the subject matters referenced in FIGS. 1a to 3.

FIG. 4a shows a solid body 102 or substrate, which is in positioned in the range of a beam source 118, particularly a LASER. Solid body 102 preferably has a first planar surface portion 141 and a second planar surface portion 116, wherein first planar surface portion 114 is preferably aligned substantially or exactly parallel to second planar surface portion 116. First planar surface portion 114 and second planar surface portion 116 preferably delimit solid body 102 in a Y-direction, which is preferably aligned vertically or perpendicularly. Planar surface portions 114 and 116 preferably each extend in an X-Z plane, said X-Z plane preferably being aligned horizontally. It may further may be inferred from this diagram that beam source 118 radiates beams 106 at solid body 102. Depending on the configuration, beams 106 penetrate solid body 102 to a defined depth and produce a fault at the respective position or at a predetermined position.

FIG. 4b shows a multilayer arrangement wherein solid body 102 includes detachment plane 108 and is furnished with a retaining layer 112 in the region of first planer surface portion 114, which retaining layer in turn is preferably overlaid by a further layer 120, wherein further layer 120 is preferably a stabilising element, particularly a metal plate. FIG. 4c shows a state after the separation of solid layer 104, wherein the separation preferably takes place as a result of the creation of modifications. According to the present invention, the crystal structure is thus modified or damaged in the separation zone by the LASER radiation in such manner that the wear layer and solid body layer 104 becomes detached or separated from the rest of solid body 102 as a consequence (preferably an immediate consequence) of the LASER treatment.

FIGS. 5a and 5b show examples of the creation of a detachment plane 108 shown in FIG. 4a by the introduction of faults or modifications into a solid body 102 by means of laser beams.

FIG. 5a thus shows schematically how faults 134 can be generated in a solid body 102, particularly for creating a detachment plane 108 by means of a radiation source 118, particularly one or more LASERs. Beam source 18 emits radiation 106 having a first wavelength 130 and a second wavelength 132. In this context, wavelengths 130, 132 are tuned to each other and the distance between beam source 118 and the detachment plane 108 to be produced is adjusted such that waves 130, 132 converge substantially or precisely on detachment plane 108 in solid body 102, with the result that the combined energies of waves 130, 132 create a fault at the site 134 where they meet. A fault may be created by different or combined degradation mechanisms such as sublimation or chemical reaction, and the decomposition may be initiated thermally and/or photochemically for example.

FIG. 5b shows a focused light beam 106, the focal point of which is preferably in detachment plane 108. In this context, it is conceivable that light beam 106 may be focused by one or more focusing elements, particularly lens(es) (not shown). In this embodiment, solid body 102 is a multilayer structure and preferably has a semi-transparent or transparent substrate layer or wear layer 103 or material layer, which preferably consists of or contains corundum, particularly sapphire. Light beams 106 pass through substrate layer 103 to detachment plane 108, which is preferably in the form of a sacrificial layer 105, and the radiation acts on sacrificial layer 105 in such manner as to partially or completely destroy sacrificial layer 105 at the focal point or in the area of the focal point by thermal and/or photochemical action. It is also conceivable that the faults intended to produce detachment layer 108 are created in the area of or precisely on a boundary surface between the two layers 103, 104. Thus it is also conceivable to produce solid layer 104 on a support layer, particularly a substrate layer 103, and that a detachment plane 108 for detachment and separation from solid layer 104 may be created by means of one or more sacrificial layers 105 and/or by means of the creation of faults in a boundary surface particularly between solid layer 104 and the carrier layer.

FIG. 6 shows a wear layer 6 generated for example according to the arrangement of FIG. 1d, particularly consisting of sapphire or a sapphire compound or containing sapphire, and a preferably at least partially transparent body 14, particularly made from a transparent polymer, a transparent glass or a transparent ceramic. Wear layer 6, which is substantially a solid body layer and preferably extends in a flat two-dimensional plane is arranged according to this variant on transparent body 14, particularly a display glass, particularly joined therewith, particularly by bonding or adhesion. Transparent body 14 can thus have a surface or shape that differs from a planar shape, in particular curved at least in sections. Further, wear layer and transparent body 14 may have different thermal stability properties, since they may be produced according to different methods. It is further conceivable that transparent body 14 is already joined to other components of an electronic device when wear layer 6 is arranged on transparent body 14. It Accordingly, a wear layer 6 may be arranged on an electronic device as shown in FIG. 3 for example.

In the variant shown, the surface of transparent body 14 on which wear layer 6 is arranged, and wear layer 6 have different curvatures. In this context (as shown) it is also conceivable that wear layer 6 is provided or produced with a flat conformation. Wear layer 6 may thus be deformed when it is arranged on the surface of transparent body 14, particularly to conform to the shape of the surface of transparent body 14 on which it is arranged or to which it is transferred. This is possible because wear layer 6 is very thin, lending it great flexibility.

Alternatively, it is conceivable that the surface of transparent body 14 on which wear layer 6 is arranged and wear layer 6 are conformed negatively and correspondingly to each other. Wear layer 6 is preferably created in such a shape that it may be arranged flush on the surface of transparent body 14 without deformation.

In this way, a solid body layer or wear layer 6 is prepared according to the inventive method. Wear layer 6 is preferably produced by the steps listed below: Providing a carrier substrate 4 with a sacrificial layer 8 arranged thereon or arranging a sacrificial layer 8 on the carrier substrate 4 provided, producing a wear layer 6 on sacrificial layer 8 by chemical or physical vapour deposition to form a multilayer arrangement 2, separating wear layer 6 as a result of a material weakness generated between wear layer 6 and carrier substrate 4, wherein the material weakening is caused by modifications 12 created in sacrificial layer 8 by means of LASER beams 10. The wear layer 6 produced in this way is then preferably structured on one or both sides as a solid body layer in the form of a two-dimensional flat plane and is arranged on a transparent body 14 which has an external shape that preferably has at least one curved portion, wherein wear layer 6 is applied particularly by bonding as a protective layer to transparent body 14, particularly a component of an electronic terminal such as a smart watch, a smart phone, tablet PC, TV, etc., in such manner that at least parts and preferably most in terms of area or all of wearing surface 6 conforms to the external shape of transparent body 14. In this way, the present invention provides that capability to protect transparent bodies such as display glasses of a smart watch, a smart phone, a tablet PC, TV, etc. effectively against damage by application of the wear layer, particularly made of sapphire.

FIG. 7A shows a carrier substrate 4 which is preferably made of a crystalline material, particularly from crystalline sapphire or crystalline silicon carbide. Preferably, a transfer layer 8 is arranged or formed on carrier substrate 4. Transfer layer 8 thus thus either be formed on carrier substrate 4 or bonded thereto. In this representation, transfer layer 8 is preferably in an amorphous state. In this context, transfer layer 8 has a thickness of preferably less than 1 μm.

FIG. 7b shows another temperature regulating device besides that of FIG. 7a, in this case particularly an electron beam source 16, by which the temperature of transfer layer is 8 controlled such that it undergoes a phase change, particularly from an amorphous state to a crystalline state a least partially and preferably mostly in terms of volume and particularly preferably completely in terms of volume. According to FIG. 7c. a wear layer 6, particularly of sapphire or silicon carbide is arranged or formed on transfer layer 8. Carrier substrate 4, transfer layer 8 and wear layer 6 together form a multilayer arrangement 2. In this context, it is conceivable that wear layer 6 is first manufactured and then mounted on transfer layer 8. Alternatively, however, wear layer 6 may also be generated on transfer layer 8. Wear layer 6 preferably as a thickness of less than 100 μm. If wear layer 6 is to be arranged on transfer layer 8, wear layer 6 is preferably partially or preferably mostly (in terms of volume) in an amorphous state. Wear layer 6 is then heated by means of a temperature control device such as an electron beam source 16, and converted from the amorphous state to a crystalline or partially crystalline state. After it has been treated or generated (on transfer layer 8), wear layer is 6 is preferably mostly or substantially completely or completely in a crystalline state.

In FIG. 8a, the multilayer arrangement 2 produced according to FIGS. 7a-7c is arranged on or bonded to a transparent body 14. Transparent body 14 may be for example a display glass, particularly of an electronic device such as a tablet PC or a smart phone.

FIG. 8B shows the creation of modifications 12 in transfer layer 8. Modifications 12 are preferably produced by means of LASER beams 10, which are emitted by a LASER, particularly a picosecond or femtosecond LASER. In this context, modifications 12 may represent or cause material transformations and/or faults such as cracks.

FIG. 8c illustrates a state after at least a portion of transfer layer 8 and carrier substrate 4 has been separated from rest of the arrangement. The separation is preferably carried out such as much material of transfer layer 8 as possible is removed from wear layer 6. This is advantageous because as a result wear layer 6 only needs to undergo little postprocessing, particularly polishing. However, since transfer layer 8 overall is thin, it is also conceivable that 50% or more of the material parts of transfer layer 8 remain on wear layer 6 after the separation. After the removal of the parts of transfer layer 8 from wear layer 6. a preferably two-layer arrangement consisting of two at least partially transparent materials with differing properties, particularly strengths, is created. Transparent body 14 preferably consists of a glass or a plastic, and wear layer 6 is made of a crystalline material.

The present invention thus relates to a method for coating at least one transparent body, particularly a display glass or a screen protection layer or a glasses lens or a helmet visor, particularly a motorcycle helmet visor. The inventive method comprises at least the steps of: forming or providing a multilayer arrangement, consisting of at least a crystalline carrier substrate, a wear layer and a transfer layer, wherein the transfer layer is arranged between the carrier substrate and the wear layer and joined to the carrier substrate and the wear layer, wherein the transfer layer is designed such that it transmits a crystal lattice information of the carrier substrate to the wear layer, wherein the wear layer is generated or treated in such manner that at least a part thereof has a crystal lattice, wherein the formation of the crystal lattice is determined at least in part by the crystal lattice information provided by the transfer layer, joining the wear layer with the at least partially transparent body, particularly a functional layer, exposing at least a portion of the multilayer arrangement to LASER beams to at least partially create modifications in the transfer layer or in the area of the join between the transfer layer and the carrier substrate or in the wear layer to generate a detachment zone, separating the multilayer arrangement along the detachment zone created particularly as a consequence of the action of the LASER beams.

Wear layer 6 is preferably designed to be mounted on a transparent body 14 such that it has at least one surface corresponding to the shape of the surface at which wear layer 6 is to be mounted on transparent body 14 or at least partially transparent body 14. Wear layer 6 preferably has a surface with a single and preferably multiple curves and particularly preferably two surfaces which are mutually parallel and describe a single curve and more preferably multiple curves. Wear layer 6 is preferably produced such that the singly curved or multiply curved surface is in a state in which wear layer 6 is not subject to constraining forces. This is advantageous because in this case wear layer 6 is not subject to any internal stresses generated from the outside and in this state it can be mounted on transparent body 14. Alternatively, however, and without departing from the scope of the present invention, wear layer 6, may also be reshaped only by the introduction of external forces to assume a shape having a singly curved or multiply curved portion or surface or surface portion. Wear layer 6, which preferably consists of sapphire or preferably contains sapphire is thus preferably produced having at least one surface that is spherical, particularly curved once or multipled time, particularly curved twice or more than twice, curved three times or more than three times, or curved four times or more than four times. Preferably, a cohesion agent, particularly an adhesion promoter or adhesive, particularly a thermosetting polymer is applied to or produced on the preferably at least one spherically shaped surface of wear layer 6, particularly the sapphire layer and/or to a surface of transparent body 14 on which wear layer 6 is arranged, to produce a cohesive connection between transparent body 14, particularly the glass such as the lens or watch glass, and wear layer 6. Preferably in this way, a sapphire layer with a spherically shaped surface is formed and is arranged on an at least partially transparent body, such as a watch glass or a glasses lens or a visor, cohesively by means of a thermosetting polymer.

Additionally or alternatively, the present invention may relate to a method for coating at least one transparent body 14, particularly a display glass or a display protection layer, comprising at least the steps of: forming or providing a multilayer arrangement 2 consisting of at least a crystalline carrier substrate 4, a wear layer 6 and a transfer layer 8, wherein transfer layer 8 is disposed between carrier substrate 4 and wear layer 6 and joined to carrier substrate 4 and wear layer 6, wherein transfer layer 8 is designed such that it transmits a crystal lattice information of carrier substrate 4 to wear layer 6, wherein the wear layer 6 is generated or treated in such manner that at least a part thereof has a crystal lattice, wherein the formation of the crystal lattice is determined at least in part on the basis of the crystal lattice information imparted by transfer layer (8), joining wear layer 6 with the at least partially transparent body 14, exposing at least a portion of multilayer arrangement 2 to LASER beams 10 for at least partial creation of modifications 12 in transfer layer 8 or in the region of the joint between transfer layer 8 and carrier substrate 4 or wear layer 6 to generate a detachment zone, separating the multilayer arrangement 2 along the detachment zone.

At least as regards the objects of FIGS. 7a-8c in this context sacrificial layer 8 may also be referred to as transfer layer 8.

The present invention further relates in preferred manner to a multilayered transparent device, particularly a display element or fingerprint sensor element or glasses lens or a visor, particularly a helmet visor. The multilayered transparent device comprising in this context preferably at least one at least partially transparent body and one at least partially transparent wear layer 6 connected to transparent body 14, wherein transparent body preferably contains a polymer material or a ceramic material or a viscous material such as glass, and wear layer 6 is made of a ceramic material, wherein wear layer 6 is harder than transparent body 14 and wherein production of the multilayer transparent device preferably includes the following step: generating the wear layer 6 by chemical or physical vapour deposition, and arranging transparent body 14 on wear layer 6, particularly by generation or bonding.

A thermosetting polymer is advantageously used for bonding the wear layer, which is preferably a sapphire layer, and the display to be protected or the glasses lens or visor to be protected. These polymers can be cured at relatively low temperatures, below 200° C., and provide stronger adhesion than thermoplastic materials. Moreover, they are very easily processable in their uncured form, particularly as a thin intermediate film of optically transparent layers 6 and 14. It is particularly advantageous that the refractive index of thermosetting polymers can be adjusted to match the refractive index of the surface which is to be protected (typically n˜1.5). In this context, bonding may be carried out as preferred before separating the wear layer 6, particularly a sapphire layer, but also after the separation of the wear layer 6, particularly the sapphire layer.

For convex or spherical transparent bodies, the base for creating wear layer 6 may also be adapted so that it already has a spherical or convex profile and wear layer 6 already assumes the profile, or at least approximates the profile of the surface to be protected when it is created. This is particularly advantageous because it makes possible curves and shapes in three dimensions which a flat wear layer 6 would otherwise not be able to assume, or might lead to undesirable stresses or distortions on the surface to be protected if the protective layer were deformed subsequently. In the case of non-flat layers, it is advantageous to bond first and remove afterwards. This avoids breaking or tearing the thin protective film.

The invention relates to a method for producing at least one solid layer, at least comprising the steps of: Providing a carrier substrate 4 with a sacrificial layer 8 arranged thereon or disposing a sacrificial layer 8 on the provided carrier substrate 4, producing a wear layer 6 by chemical or physical vapour deposition on sacrificial layer 8 to form a multilayer arrangement 2, separating wear layer 6 by means of a material weakening between wear layer 6 and carrier substrate 4 induced as consequence of a controlled crack, wherein the crack brings about the material weakening in controlled manner as a result of modifications created in sacrificial layer 8 by LASER beams 10.

LIST OF REFERENCE NUMBERS

| | | | |
|---|---|---|---|
| 2 | Multilayer arrangement | 14 | Transparent body |
| 4 | Carrier substrate | 18 | Electronic device |
| 6 | Wear layer | 20 | Display glass |
| 8 | Sacrificial layer | 22 | Curved portion |
| 10 | LASER beams | 23 | Selection element |
| 11 | LASER | 24 | Frame |
| 12 | Modifications | 102 | Solid body |
| 103 | Substrate | 116 | Second flat surface portion |
| 104 | Solid layer | 118 | Radiation source |
| 105 | Sacrificial layer | 120 | Stabilising element |
| 106 | Radiation | 130 | First beam portion |
| 108 | Detachment plane | 132 | Second beam portion |
| 112 | Retaining layer | 134 | Site of fault creation |
| 114 | First flat surface portion | | |

1. A method for producing at least one solid layer, comprising at least the steps of:
Providing a carrier substrate (4) having a sacrificial layer (8) disposed thereon or arranging a sacrificial layer (8) on the provided carrier substrate (4),
Generating a wear layer (6) on the sacrificial layer (8) by chemical or physical vapour deposition to form a multilayer arrangement (2),
Separating the wear layer (6) as a consequence of a material weakening created between the wear layer (6) and the carrier substrate (4)
wherein the material weakening is caused by modifications (12) generated in the sacrificial layer (8) by LASER beams (10).

2. Method for coating at least a transparent body (14), particularly a display glass (20) or a display protector layer,
comprising at least the steps of:
Arranging or producing the at least partly transparent body (14), particularly made of plastic, glass or a ceramic material, on a wear layer (6) produced according to claim,
or
Providing a carrier substrate (4) with a sacrificial layer (8) disposed thereon or arranging a sacrificial layer (8) on the carrier substrate (4) provided,
Generating a wear layer (6) by chemical or physical vapour deposition on the sacrificial layer (8) to form a multilayer arrangement (2),
Arranging or generating the at least partially transparent body (14) on the wear layer (6),
Separating the wear layer (6) as a consequence of a material weakening created between the wear layer (6) and the carrier substrate (4)
wherein the material weakening is caused by modifications (12) generated in the sacrificial layer (8) by LASER beams (10).

3. Method according to claim 2,
characterised in that
the at least partly transparent body (14) is made from a polymer material, wherein the transparent body (14) has a lower modulus of elasticity than the wear layer (6), particularly a modulus of elasticity that is lower by a factor of at least 10 or a factor of 100.

4. Method according to claim 2 or 3,
characterised in that
the wear layer (6) and the transparent body (14) have an external shape with at least one curved portion (22),
wherein the modifications (12) for conducting a crack in the sacrificial layer (8) and/or the wear layer (6) are created corresponding to the external shape of the wear layer (6), or wherein the sacrificial layer (8) is produced with a surface that is curved in such a manner, or the surface of the sacrificial layer (8) is processed after production of the sacrificial layer (8) in such manner that it forms a curved surface shape, and the wear layer (6) is created with a corresponding shape due to its creation on the curved surface of the sacrificial layer (8)
or
the wear layer (6) substantially as a solid layer with a two-dimensional flat plane and the transparent body (14) has an external shape which includes at least one curved portion, wherein the wear layer (6) is applied to the transparent body (14) in such manner, particularly by bonding, that the wear layer (6) conforms to the outer shape of the transparent body (14).

5. Method according to any one of the preceding claims, characterised in that
the wear layer (6) consists of a ceramic material, particularly silicon carbide (SiC) or aluminium oxide (Al₂O₃) and is created in an amorphous or polycrystalline state particularly by sputtering, wherein the wear layer (6) the ceramic material is cured by means of thermal treatment at temperatures higher than 500° C. preferably higher than 700° C. and particularly preferably higher than 1000° C. after or during production of the wear layer (6),
wherein the ceramic material preferably comprises corundum, which is produced in a gamma phase or alpha phase.

6. Method according to any one of the preceding claims, characterised in that
the wear layer (6) is thinner than 100 μm and preferably thinner than 50 μm and particularly preferably 20 μm thick or thinner than 20 μm.

7. Method according to any one of the preceding claims, characterised in that
the modifications (12) are local cracks in the crystal lattice and/or are material parts transferred into another phase and/or the modifications (12) are created by means of LASER radiation (10) introduced over an outer surface of the multilayer arrangement (2) from at least one picosecond or femtosecond LASER.

8. Method according to any one of the preceding claims, characterised in that
the wear layer (6) is separated by means of a crack guided between the wear layer (6) and the carrier substrate (4)
wherein the crack is guided by modifications (12) generated in the sacrificial layer (8) by LASER beams (10) and/or
wherein stresses for initiating and/or propagating the crack are generated via a thermal shock to a stress-inducing layer (16) arranged additionally on the multilayer arrangement (2)
the stress-inducing layer (16) contains or consists of a polymer, particularly polydimethylsiloxane (PDMS), wherein the thermal shock is applied in such manner that the polymer undergoes a glass transition, wherein the temperature of the stress-inducing layer (16) is adjusted particularly by means of liquid nitrogen to a temperature at which the polymer undergoes at least partial and preferably complete glass transition, in which the temperature of polymer is preferably cooled to a temperature below room temperature or below 0° C. or below −50° C. or below −100° C. or below −110° C., particularly to a temperature below the glass transition temperature of the stress-inducing layer (16), or the temperature is adjusted a temperature above room temperature, particularly to a temperature between 40° C. and 180° C.

9. Method according to any one of the preceding claims, characterised in that
the LASER beams (10) are emitted by at least one LASER device (11), wherein the LASER device (11) for providing the LASER beams (10) to be introduced into the wear layer (6) and/or the sacrificial layer (8) is configured in such manner that the LASER beams (10) emitted thereby create the modifications (12) at predetermined locations within the wear layer (6) and/or the sacrificial layer (8), wherein the LASER device (11) is adjusted such that the LASER beams (10) emitted thereby for generating the modifications (12) penetrate the wear layer (6) and/or the sacrificial layer (8) to a defined depth of less than 200 μm, preferably less than 100 μm and more preferably less than 50 μm and particularly preferably less than 20 μm, wherein the LASER device (11) has a pulse duration of less than 10 ps preferably less than 1 ps and particularly preferably less than 500 fs.

10. Method according to any one of the preceding claims, characterised in that
the LASER device (11) comprises a femtosecond LASER (fs LASER) and the energy of the LASER beams (10) of the fs-LASER is chosen such that the propagation of the damage of any modification (12) in the wear layer (6) and/or the sacrificial layer (8) is less than 3 times the Rayleigh length, preferably less than the Rayleigh length and particularly preferably less than one-third of the Rayleigh length
and/or
the wavelength of the LASER beams (10) of the fs-LASER is chosen such the absorption by the wear layer (6) and/or the sacrificial layer (8) is less than 10 cm⁻¹ and preferably less than 1 cm⁻¹ and more preferably less than 0.1 cm⁻¹
and/or the individual modifications (12) are each generated as a consequence of a o multi-photon excitation effected by the fs-LASER.

11. Method according to any one of the preceding claims, characterised in that
the carrier substrate (4) is crystalline and the sacrificial layer (8) serves as a transfer layer, wherein the transfer layer (8) is arranged between the carrier substrate (4) and the wear layer (6) and is joined to the carrier substrate (4) and the wear layer (6),
wherein the sacrificial layer (8) is designed such that it transfers a crystal lattice information of the carrier substrate (4) to the wear layer (6),
wherein the wear layer (6) is produced or treated in such manner that at least part thereof has a crystal lattice,
wherein the formation of the crystal lattice is based at least in part on the crystal lattice information provided by the transfer layer (8).

12. Method according to claim 11,
characterised in that
the wear layer (6) converted from an amorphous state to an at least partially, particularly mostly crystalline state as a consequence of a temperature change, wherein the wear layer (6) receives the crystal lattice information provided by the transfer layer (8) when changing states, wherein the temperature change is preferably effected by exposure to an electron beam.

13. Method according to claim 10 or claim 11, characterised in that
the sacrificial layer (8) is produced on the carrier substrate (4) in a crystalline state or arranged on the carrier substrate (4) in an amorphous state, and is converted at least partly and preferably mostly or completely to a crystalline state by a thermal shock, or
the carrier substrate (4) and the wear layer (6) consist of the same material, particularly sapphire or silicon carbide, and the sacrificial layer (8) consists of a different material from the material of the carrier substrate (4) and the wear layer (6), particularly silicon.

14. Method according to any one of claims 10 to 12 characterised in that
the wear layer (6) is thinner than 100 μm and preferably thinner than 50 μm and particularly preferably 20 μm thick or thinner than 20 μm
and the sacrificial layer (8) is thinner than 10 μm and preferably thinner than 5 μm and particularly preferably 1 μm thick or thinner than 1 μm.

15. Multilayer transparent device, particularly a display element or fingerprint sensor element or glasses lens or visor, particularly a helmet visor,
comprising at least an at least partially transparent body (14) and an at least partially transparent wear layer (6) connected to the transparent body (14),
wherein the transparent body (14) preferably contains a polymer material or a ceramic material or a viscous material such as glass, and said wear layer (6) consists of a ceramic material, wherein the wear layer (6) is harder than the transparent body (14) and
wherein the production of the multilayer transparent device comprises at least the following steps:
Generating the wear layer (6) by chemical or physical vapour deposition and
Arranging the transparent body (14) on the wear layer (6), particularly by generation or bonding.

16. Electronic device (18),
at least comprising an image signal processing device and a display device for outputting an image signal processed by the image signal processing device, characterised in that
at least the display device and/or an optically conductive further part, such as a camera cover or a fingerprint sensor or a separate area of a touch screen, is at least partially or completely overlaid by a multilayer transparent display protector according to claim 14.
